(19) United States
(12) Patent Application Publication
(10) Pub. No.: US 2025/0364275 A1
(43) Pub. Date: Nov. 27, 2025

(54) METHOD AND APPARATUS FOR FORMING SEMICONDUCTOR DEVICE

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR); YoungHoon JEON, Incheon (KR)

(21) Appl. No.: 19/216,771

(22) Filed: May 23, 2025

(30) Foreign Application Priority Data
May 27, 2024 (CN) 202410665523.1

(51) Int. Cl. H01L 21/56; H01L 21/67

(52) U.S. Cl. CPC H01L 21/565; H01L 21/67115

(57) ABSTRACT

A method and an apparatus for forming a semiconductor device are provided. The method includes: providing a substrate; mounting at least one electronic component on a surface of the substrate; forming an encapsulant on the surface of the substrate to encapsulate the electronic component; loading the substrate into a semiconductor device magazine; and irradiating the encapsulant with a microwave radiation to cure the encapsulant.

### TECHNICAL FIELD

The present application generally relates to semiconductor technology, and more particularly, to a method for forming a semiconductor device and an apparatus for forming a semiconductor device.

### BACKGROUND OF THE INVENTION

The semiconductor industry is constantly faced with complex integration challenges as consumers want their electronics to be smaller, faster and higher performance with more and more functionalities packed into a single device. Usually, an encapsulant may be deposited over a semiconductor package to provide physical support and electrical isolation. The encapsulant may be placed into an oven, and convective heat transfer is used to heat and cure the encapsulant. However, the thermal curing process has some problems associated with it. For example, by using convective heat transfer, the entire semiconductor package, but not just the encapsulant that is desired to be cured, is heated. Because different materials in the semiconductor package have different coefficients of thermal expansion, stresses will form as the different materials expand at different rates due to the heating, resulting in warpage in the semiconductor package and possible damages to other electronic components. Recently, laser assisted heating technology has been researched and developed to cure the encapsulant. However, this technology has limitations in mass production.

Therefore, a need exists for a semiconductor manufacturing method suitable for mass production.

### SUMMARY OF THE INVENTION

An objective of the present application is to provide a method for forming a semiconductor device, which is suitable for mass production.

According to an aspect of the present application, a method for forming a semiconductor device is provided. The method may include: providing a substrate; mounting at least one electronic component on a surface of the substrate; forming an encapsulant on the surface of the substrate to encapsulate the electronic component; loading the substrate into a semiconductor device magazine; and irradiating the encapsulant with a microwave radiation to cure the encapsulant.

According to another aspect of the present application, a method for forming a semiconductor device is provided. The method may include: providing a semiconductor package including at least one curable material; loading the substrate into a semiconductor device magazine; and irradiating the curable material with a microwave radiation to cure the curable material.

According to still another aspect of the present application, an apparatus for forming a semiconductor device is provided. The apparatus may include: a heating chamber; a heating source mounted inside the heating chamber and configured for irradiating a microwave radiation; and a semiconductor device magazine disposed inside the heating chamber and configured for carrying a semiconductor package including at least one curable material, wherein the curable material can be cured when irradiated by the microwave radiation.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E are cross-sectional views illustrating various steps of a method for forming a semiconductor device according to an embodiment of the present application.

FIG. 2 is a perspective view illustrating an apparatus for forming a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

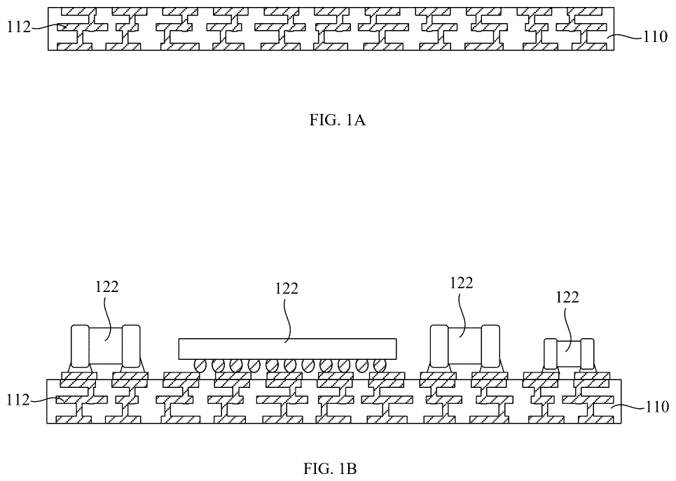

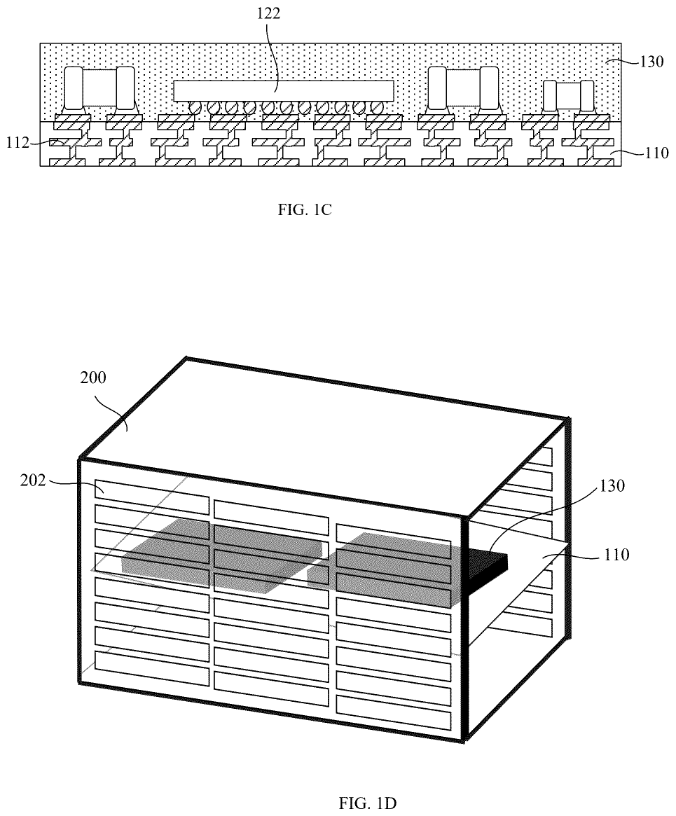

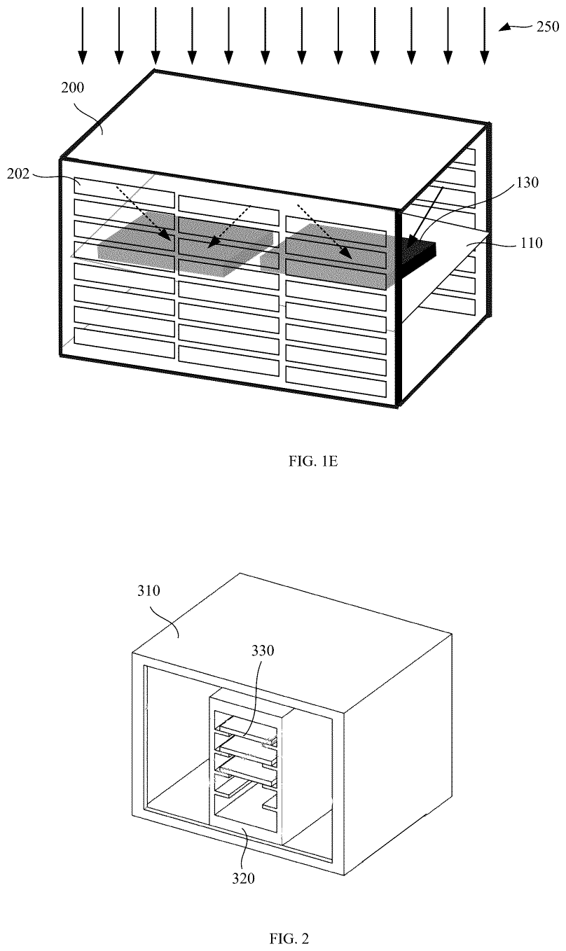

Referring to FIGS. 1A to 1E, various steps of a method for forming a semiconductor device are illustrated according to an embodiment of the present application. In the following, the method will be described with reference to FIGS. 1A to 1E in more details.

As shown in FIG. 1A, a substrate 110 is provided. The substrate 110 can provide support and connectivity for electronic components and devices.

By way of example, the substrate 110 can include a printed circuit board (PCB), a carrier substrate, a semiconductor substrate with electrical interconnections, or a ceramic substrate. However, the substrate 110 is not to be limited to these examples. In other examples, the substrate 110 may include a laminate interposer, a strip interposer, a leadframe, or other suitable substrates. The substrate 110 may include any structure on or in which an integrated circuit system can be fabricated. For example, the substrate 110 may include one or more insulating or passivation layers, one or more conductive vias formed through the insulating layers, and one or more conductive layers formed over or between the insulating layers.

In some embodiments, the substrate 110 may include a plurality of interconnection structures 112. The interconnection structures 112 can provide connectivity for electronic components mounted on the substrate 110. The interconnection structures 112 may include one or more of Cu, Al, Sn, Ni, Au, Ag, or any other suitable electrically conductive materials. In some examples, the interconnection structures 112 may include redistribution structures. The redistribution structures may include one or more dielectric layers and one or more conductive layers between and through the dielectric layers. The conductive layers may define pads, traces and plugs through which electrical signals or voltages can be distributed horizontally and vertically across the redistribution structures. As shown in FIG. 1A, the interconnection structures 112 can provide contact pads along the top surface and the bottom surface of the substrate 110 for mounting devices, chips, and interconnects thereon.

Referring to FIG. 1B, one or more electronic components 122 are mounted on the top surface of the substrate 110.

The electronic components 122 may include any of a variety of types of semiconductor dice, semiconductor packages, or discrete devices. For example, the electronic components 122 may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, a discrete device, etc. In some embodiments, solder materials may be deposited onto the contact pads formed on the top surface of the substrate 110, and the electronic components 122 are placed on the top surface of the substrate 110 and in contact with the solder materials. Then, the solder materials may be reflowed to mount the electronic components 122 on the top surface of the substrate 110 via the solder materials, thus forming electrical connection therebetween.

In the example of FIG. 1B, the electronic components 122 include a semiconductor die, and multiple discrete devices such as resistors, capacitors, inductors, etc. The semiconductor die is mounted on the surface of the substrate 110 by a flip-chip bonding technique, such that conductive bumps of the semiconductor die are welded to some of the contact pads on the top surface of the substrate 110. In other examples, the semiconductor die may include bond pads and may be connected to the contact pads by a wire bonding technique. It could be understood that the semiconductor die and the discrete devices illustrated in FIG. 1B are only examples, and the present application is not limited thereto.

Referring to FIG. 1C, an encapsulant 130 is formed on the top surface of the substrate 110 to encapsulate the electronic components 122.

In some embodiments, the encapsulant or epoxy molding compound (EMC) 130 is deposited over the top surface of the substrate 110 using a transfer molding, compression molding, paste printing, liquid encapsulant molding, vacuum lamination, spin coating, or other suitable applicator. For example, the encapsulant 130 is disposed alongside surfaces of the electronic components 122 and thus covers each side surface of the electronic components 122. The encapsulant 130 can be polymer composite material, such as epoxy resin with filler, epoxy acrylate with filler, or polymer with proper filler. The encapsulant 130 is non-conductive and environmentally protects the semiconductor device from external elements and contaminants.

Referring to FIG. 1D, the substrate 110 is loaded into a semiconductor device magazine 200.

The semiconductor device magazine 200 may be a standard carrier widely used for storing and moving of printed circuit boards (PCBs) or lead frames. As shown in FIG. 1D, the semiconductor device magazine 200 may include multiple pairs of guide rails (or slots, not shown) on its sidewalls. The multiple pairs of guide rails are arranged in a vertical direction at an interval. Each pair of guide rails are configured to guide and support opposite edges of the substrate 110. As shown in FIG. 1D, the substrate 110 may fit between and extends between the guide rails of the semiconductor device magazine 200. As can be seen, the semiconductor device magazine 200 can provide protection for handling or transporting a plurality of substrates 110.

In some embodiments, the semiconductor device magazine 200 may have a plurality of apertures 202 formed on its sidewalls, such that electromagnetic waves of a microwave radiation used in a subsequent step can pass through the semiconductor device magazine 200 to irradiate the encapsulant 130 on the surface of the substrate 110. In the present application, the semiconductor device magazine 200 may also be used to reflect radiation energy from the microwave radiation used in the subsequent step. Thus, the semiconductor device magazine 200 may have a high reflectivity over the spectrum of the microwave radiation. In some embodiments, the reflectivity of the semiconductor device magazine 200 to the spectrum of the microwave radiation is at least greater than that of the encapsulant 130, preferably, greater than 50%, 60%, 70%, 80%, 90%, or 95%. By way of example, the semiconductor device magazine 200 may include a metallic material which has a high damping constant, leading to a short distance crossed by the microwave. For example, the semiconductor device magazine 200 may include Al, Cu, Ag, Au, etc., which has a high reflectivity in a wide range of wavelengths.

Referring to FIG. 1E, the encapsulant 130 is cured with a microwave radiation.

After the substrate 110 has been loaded into the semiconductor device magazine 200, the encapsulant 130 may be cured by irradiating the encapsulant 130 with microwave radiation 250 (represented by arrows in FIG. 1E). For example, the electromagnetic waves of the microwave radiation 250 may pass through the apertures 202 of the semiconductor device magazine 200 to irradiate the encapsulant 130 on the surface of the substrate 110. The microwave radiation 250 is used to generate heat in the encapsulant 130 at the molecular level by forcing any polar bonds in the encapsulant 130 to oscillate. Further, the microwave radiation 250 may be chosen so as to heat the encapsulant 130 without significantly heating the other structures, such as the electronic components 122.

Specifically, the microwave radiation 250 can induce molecular rotation in the encapsulant 130 without destroying molecular bonds due to low energy per photon. The electric field generated by the microwave radiation 250 may have effect on organic materials composed of polar molecule, and the electric field can distort the negative cloud of electrons around positive atomic nuclei in a direction opposite the electric field. The molecules including the electrons may rotate according to the electric field direction, and thus the rotating molecules collide with neighboring molecules and friction energy from molecular collision converts into heat energy. Therefore, the heat energy heats the encapsulant 130 volumetrically at all points within the encapsulant 130. This type of heating does not depend upon a heating of only the outer skin of the encapsulant 130 followed by thermal conductivity to the interior of the encapsulant 130. Using the microwave radiation 250 to heat the encapsulant 130 with polar bonds additionally allows the curing process to self-regulate itself. As stated above, forced oscillations of the polar bonds cause the encapsulant 130 to be heated by the microwave radiation 250. Once the individual molecules of the encapsulant 130 have been heated to the cure temperature, the molecules will react, thereby significantly reducing or eliminating the polar bonds. After the reaction has occurred, there are less polar bonds that are heated by the microwave radiation 250, thereby resulting in less heat generated after the reaction, and stopping the curing process once the encapsulant 130 has cured.

Compared with a conventional heating process in which heat energy is transmitted by conduction and convection, heat energy in a microwave heating process is transmitted by radiation, for example, the encapsulant 130 is directly heated by microwave radiation 250, with an improved heating efficiency. Accordingly, the microwave heating process reduces loss of heat energy and increases reaction rate by molecule dipole moment rotation under a variation of microwave field.

In some embodiments, a frequency of the microwave radiation 250 necessary to cure the encapsulant 130 is dependent upon the material to be used as the encapsulant 130. For example, the frequency of the microwave radiation 250 may be within the microwave band between about 1 GHz and about 1,000 GHz. In an example, the frequency of the microwave radiation 250 is within the C band of microwave radiation, between about 5.8 GHz and about 7.0 GHz. In some embodiments, the encapsulant 130 may be irradiated with the microwave radiation 250 for a duration ranging between 10 seconds and 10 minutes, for example, 1 minute, 3 minutes, or 5 minutes. However, the present application is not limited to the above examples.

In some embodiments, the frequency of the microwave radiation 250, once chosen based upon the material to be used as the encapsulant 130, be generated as a variable frequency microwave (VFM) radiation. In other words, once a primary frequency has been chosen for the microwave radiation 250, it is preferred that the curing of the microwave radiation 250 occur such that the actual frequency sweeps through a range of frequencies centered around the chosen frequency, with a preferred range of about ±0.6 GHz from the central frequency. The variable frequency microwave radiation is especially suitable for processing semiconductor materials and thin film coatings. In particular, the continuous sweeping of frequencies over the available bandwidth can reduce the potential for arcing and subsequent damage.

Moreover, as described above, the semiconductor device magazine 200 may have a high reflectivity over the spectrum of the microwave radiation, and the electromagnetic waves of the microwave radiation 250 can be reflected multiple times within the semiconductor device magazine 200 and thus are significantly prevented from escaping from the semiconductor device magazine 200. That is, the electromagnetic waves of the microwave radiation 250 can be trapped in the semiconductor device magazine 200, thereby facilitating the absorption of the electromagnetic waves by the encapsulant 130. As can be seen in FIG. 1E, after several times of reflections by sidewalls of the semiconductor device magazine 200, the electromagnetic waves of the microwave radiation 250 are trapped in the semiconductor device magazine 200. According to an experiment conducted by inventors of the present application, while a temperature of the encapsulant 130 inside the semiconductor device magazine 200 is about 90° C., a temperature outside the semiconductor device magazine 200 is about 80° C.

Thus, the method in the above embodiments employes the microwave radiation technique and the microwave reflection effect of the magazine 200 to induce faster curing reaction of the encapsulant 130, and is suitable for mass production with enhanced UPH (unit per hour).

In the examples of FIG. 1A to FIG. 1E, it is only illustrated a single unit of semiconductor device, but the present application is not limited thereto. Usually, a strip type of semiconductor devices, i.e., a plurality of semiconductor devices arranged in a strip manner, may be provided. The plurality of semiconductor devices may be isolated from each other by singulation channels. The singulation channels can provide cutting areas to singulate the semiconductor strip into individual semiconductor devices.

In the embodiment described with reference to FIGS. 1A to 1E, the method of the present application can be used to cure the encapsulant formed on the substrate. However, the present application is not limited thereto.

In some other embodiments, the method of the present application can be used to cure any curable material used in a semiconductor package. In some embodiments, the method can be used to cure an organic material containing polar molecules, for example, an adhesive, an epoxy molding compound or a flux solution. In some embodiments, the method can be used to cure a soldering material. For example, the soldering material may be heated by the microwave radiation at the outer skin, followed by a heat transfer to the interior of the soldering material. Thus, any curable material that may be brought to a curable temperature by microwave radiation may alternatively be used in the method of the present application. For example, polymers, silicone, related co-polymers, metals (such as Au, Ag, Cu, Al, or Sn), combinations of these, or the like may alternatively be used instead of an encapsulant.

According to another aspect of the present application, an apparatus for forming a semiconductor device is provided.

As shown in FIG. 2, the apparatus may include a heating chamber 310, a heating source (not shown) and a semiconductor device magazine 320. The heating source may be mounted inside the heating chamber 310 and configured for irradiating a microwave radiation, and the semiconductor device magazine 320 may be disposed inside the heating chamber 310 and configured for carrying a plurality of semiconductor package 330 including at least one curable material. The curable material can be cured when irradiated by the microwave radiation. The semiconductor device magazine 320 may be the same as or similar to the semiconductor device magazine 200 illustrated in FIGS. 1D and 1E, and will not be elaborated herein.

In some embodiments, the curable material may include an organic material containing polar molecules. In some embodiments, the curable material comprises an adhesive, an epoxy molding compound, a flux solution, or a soldering material. In some embodiments, the semiconductor device magazine 320 may have a plurality of apertures through which the microwave radiation can pass through to irradiate the curable material of the semiconductor package 330. In some embodiments, the semiconductor device magazine 320 may include a material with a high reflectivity, such as Al, Cu, Ag, or Au. In some embodiments, the microwave radiation irradiated by the heating source may be a variable frequency microwave radiation.

More details about the apparatus may refer to the methods described in the above embodiments, and will not be elaborated herein.

The discussion herein included numerous illustrative figures that showed various portions of a method for forming a semiconductor device and an apparatus for forming the same. For illustrative clarity, such figures did not show all aspects of each example device. Any of the example apparatus and/or methods provided herein may share any or all characteristics with any or all other apparatus and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor device, comprising:
providing a substrate;
mounting at least one electronic component on a surface of the substrate;
forming an encapsulant on the surface of the substrate to encapsulate the electronic component;
loading the substrate into a semiconductor device magazine; and
irradiating the encapsulant with a microwave radiation to cure the encapsulant.

2. The method of claim 1, wherein the semiconductor device magazine has a plurality of apertures through which the microwave radiation can pass through to irradiate the encapsulant on the surface of the substrate.

3. The method of claim 1, wherein the semiconductor device magazine comprises a material with a high reflectivity.

4. The method of claim 3, wherein the semiconductor device magazine comprises Al, Cu, Ag, or Au.

5. The method of claim 1, wherein the microwave radiation is a variable frequency microwave (VFM) radiation.

6. The method of claim 1, wherein a frequency of the microwave radiation ranges from 1 GHz to 1000 GHz.

7. The method of claim 1, wherein irradiating the encapsulant with the microwave radiation comprises:
irradiating the encapsulant with the microwave radiation for a duration ranging between 10 seconds and 10 minutes.

8. A method for forming a semiconductor device, comprising:
providing a semiconductor package comprising at least one curable material;
loading the semiconductor package into a semiconductor device magazine; and
irradiating the semiconductor package with a microwave radiation to cure the curable material of the semiconductor package.

9. The method of claim 8, wherein the curable material comprises an organic material containing polar molecules.

10. The method of claim 8, wherein the curable material comprises an adhesive, an epoxy molding compound, a flux solution, or a soldering material.

11. The method of claim 8, wherein the semiconductor device magazine has a plurality of apertures through which the microwave radiation can pass through to irradiate the semiconductor package.

12. The method of claim 8, wherein the semiconductor device magazine comprises a material with a high reflectivity.

13. The method of claim 12, wherein the semiconductor device magazine comprises Al, Cu, Ag, or Au.

14. The method of claim 8, wherein the microwave radiation is a variable frequency microwave (VFM) radiation.

15. The method of claim 8, wherein a frequency of the microwave radiation ranges from 1 GHz to 1000 GHz.

16. The method of claim 8, wherein irradiating the semiconductor package with the microwave radiation comprises:
irradiating the semiconductor package with the microwave radiation for a duration ranging between 10 seconds and 10 minutes.

17. An apparatus for forming a semiconductor device, comprising:
a heating chamber;
a heating source mounted inside the heating chamber and configured for irradiating a microwave radiation; and
a semiconductor device magazine disposed inside the heating chamber and configured for carrying a semiconductor package comprising at least one curable material, wherein the curable material can be cured when irradiated by the microwave radiation.

18. The apparatus of claim 17, wherein the semiconductor device magazine has a plurality of apertures through which the microwave radiation can pass through to irradiate the curable material of the semiconductor package.

19. The apparatus of claim 17, wherein the semiconductor device magazine comprises a material with a high reflectivity.

20. The apparatus of claim 17, wherein the microwave radiation is a variable frequency microwave (VFM) radiation.
